(19) United States
(12) Patent Application Publication
(10) Pub. No.: US 2015/0276822 A1
(43) Pub. Date: Oct. 1, 2015

(54) LIGHTNING DETECTION CIRCUIT ASSEMBLY

(71) Applicant: AJOHO ENTERPRISE CO., LTD., Taipei City (TW)

(72) Inventors: Chia-Ping MO, Taipei City (TW); You-Chi LIU, Taipei City (TW)

(21) Appl. No.: 14/735,735

(22) Filed: Jun. 10, 2015

Related U.S. Application Data
(63) Continuation-in-part of application No. 14/180,854, filed on Feb. 14, 2014.
Application No. 14/180,854 is a continuation-in-part of application No. 13/544,538, filed on Jul. 9, 2012, now Pat. No. 8,878,628.

(30) Foreign Application Priority Data
Apr. 6, 2012 (TW) 101112238
Sep. 16, 2014 (TW) 103216440

(51) Int. Cl. G01R 19/00

(52) U.S. Cl. CPC G01R 19/0092

(57) ABSTRACT

A lightning detection circuit assembly includes electrical connector including signal input terminal and signal processing system, and lightning detection circuit including resistor electrically connected with one end thereof to the electrical connector, grounding terminal electrically connected to the opposite end of the resistor and output terminal electrically connected to the end of the resistor that is electrically connected to the electrical connector. When the signal input terminal receives high current or high voltage of abnormal surge (lightning), the high voltage is transmitted to the lightning detection circuit and then discharged by the resistor through the grounding terminal, and at the same time, the resistor converts the surge into a data signal for output through the output terminal to external electronic device for recording, and thus the external electronic device can record the frequency, time or intensity of occurred surges (lightning) for reference in a further maintenance or inspection work.

This application is a Continuation-In-Part of co-pending application Ser. No. 14/180,854, filed on Feb. 14, 2014, which is a Continuation-In-Part of application Ser. No. 13/544,538, filed on Jul. 9, 2012; for which priority is claimed under 35 U.S.C. §120, the entire contents of which are hereby incorporated by reference. This application claims the priority benefit of Application No. 103216440 filed in Taiwan on Sep. 16, 2014 and Application No. 101112238 filed in Taiwan on Apr. 6, 2012.

### BACKGROUND OF THE INVENTION

1. Field of the Invention

The present invention relates to network technology and more particularly, to a lightning detection circuit assembly, which comprises an electrical connector and a lightning detection circuit, wherein when a high current invasion occurred on the input side of the electrical connector, the resistor of the lightning detection circuit discharges the high current to the earth and provides a corresponding data signal through an output terminal to an external electronic device so that the external electronic device can record the frequency, time or intensity of occurred surges (lightning) for further reference.

2. Description of the Related Art

With fast development of computer technology, desk computers and notebook computers are well developed and widely used in different fields for different applications. It is the market trend to provide computers having high operating speed and small size. Further, network communication technology brings people closer together, helping people to gather information about living, learning, working and recreational activities. By means of network communication, people can communicate with one another to send real time information, advertising propaganda or e-mail. Further, through the Internet, people can search information, send instant messages, or play on-line video games. The development of computer technology makes the relationship between people and network unshakable and inseparable.

In a network, cable or wireless interference means may be selectively used for data transmission. The technology of cable connection for network application needs to use network connectors. With the development of network applications, the data transmission capacity is greatly increased. In order to satisfy users demands, network connection speed has been greatly improved from the rate of 10 Mbps up to 100 Mbps or 1 Gbps. The advanced fiber optic network speed can support 10 Gbps. However, if a network signal line gets struck by a lightning, the unusual electrical surge from the lightning strike can affect signal transmission stability, interrupting the connection, or causing damage to the network chip, circuit board or other connected electronic components or devices (computer, router, etc.). Computer networks are categorized by their scope or scale. The usually said categories of networks are LAN (local area network), MAN (metropolitan area network), WAN (wide area network). The most well-known WAN is the Internet. When linking a network signal, or uploading or downloading network data, external electromagnetic noises and internal surging noises (such as lightning strikes) can affect signal transmission stability. Therefore, it is necessary to install filter devices in network connectors for removing noises, electromagnetic waves and voltage surges. However, the filter devices of conventional network connectors cannot effectively remove all instantaneous high voltage surges caused by lightning strikes to prevent damage to the network chip and other connected electronic components.

During the operation of a power connector or USB connector to deliver current electricity or electronic signal, the current electricity or electronic signal can easily be interfered by the signals or electromagnetic noises of surrounding electronic components, or a surge (such as lightning) can occur on the signal under delivery. The abnormal high current or high voltage of a surge (lightning) can cause damage to the electronic device that carries the electrical connector (such as network connector, power connector or USB connector). Conventional electrical connectors are normally equipped with a metal shielding shell or an anti-lightning circuit for discharging abnormal surges to the earth, preventing electronic device damage. However, these measures cannot record or display occurred surges. When performing a subsequent testing, maintenance, repair or components replacement work, we cannot judge whether or not the surge removal circuit, structure or equipment has to be detected or updated due to lack of the data of the frequency, time or intensity of occurred surges, and thus, we are unable to strengthen the preventive work in advance, or to make the correct control on the abnormal conditions of the electronic device.

Therefore, it is desirable to provide a measure that eliminates the problem of being unable to know the data of the frequency, time or intensity of surges occurred on the electrical connectors of an electronic apparatus for reference in performing a subsequent maintenance or update operation.

### SUMMARY OF THE INVENTION

The present invention has been accomplished under the circumstances in view. It is therefore the main object of the present invention to provide a lightning detection circuit assembly, which comprises an electrical connector and a lightning detection circuit, wherein when a high current invasion occurred on the input side of the electrical connector, the resistor of the lightning detection circuit discharges the high current to the earth and provides a corresponding data signal through an output terminal to an external electronic device so that the external electronic device can record the frequency, time or intensity of occurred surges (lightning) for further reference.

To achieve this and other objects of the present invention, a lightning detection circuit assembly comprises an electrical connector, which comprises a signal input terminal and a signal processing system, and a lightning detection circuit, which comprises a resistor electrically connected with one end thereof to the electrical connector, a grounding terminal electrically connected to the opposite end of the resistor and an output terminal electrically connected to the end of the resistor that is electrically connected to the electrical connector. When the signal input terminal of the electrical connector receives a high current or high voltage of an abnormal surge (lightning), the high voltage is transmitted to the lightning detection circuit and then discharged by the resistor through the grounding terminal, and at the same time, the resistor converts the surge into a data signal for output through the output terminal to an external electronic device for recording, and thus the external electronic device can record the frequency, time or intensity of occurred surges (lightning) for reference in a further maintenance or inspection work.

Further, the electrical connector can be a network connector, power connector or USB connector in a signal processing system of an electronic product or computer. Further, the external electronic device can be a host computer, surveillance system, memory of signal processing system, CPU or IC chip with memory function for recording the frequency, time or intensity of occurred surges (lightning).

### BRIEF DESCRIPTION OF THE DRAWINGS

FIG. 1 is a circuit block diagram of a lightning detection circuit assembly in accordance with the present invention.

FIG. 2 is a circuit diagram of the lightning detection circuit assembly in accordance with the present invention.

### DETAILED DESCRIPTION OF THE PREFERRED EMBODIMENT

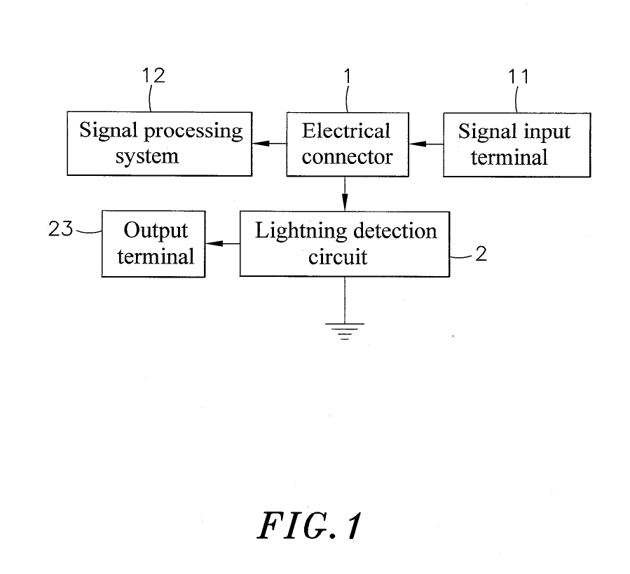

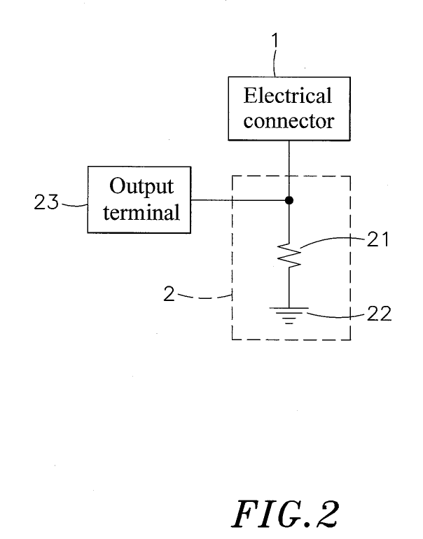

Referring to FIGS. 1 and 2, a lightning detection circuit assembly in accordance with the present invention is shown. As illustrated, the lightning detection circuit assembly comprises an electrical connector 1, and a lightning detection circuit 2.

The electrical connector 1 can be a network connector, power connector or USB connector, and electrically coupled with a signal input terminal 11 at one end thereof and a signal processing system 12 at an opposite end thereof.

The lightning detection circuit 2 comprises a resistor 21, a grounding terminal 22 electrically connected to one end of the resistor 21, and an output terminal 23 electrically connected to an opposite end of the resistor 21.

In installation, the end of the resistor 21 of the lightning detection circuit 2 that is electrically coupled with the output terminal 23 is electrically connected to the electrical connector 1, so that the lightning detection circuit 2 can receive an electronic signal (current, voltage, etc.) from the electrical connector 1. Thus, the electrical connector 1 and the lightning detection circuit 2 are assembled, constituting the lightning detection circuit assembly.

When the signal input terminal 11 of the electrical connector 1 receives a normal electronic signal (low current or low voltage signal) without producing an abnormal surge, the electrical connector 1 does not provide any abnormal high current or high voltage to the lightning detection circuit 2; however, if the signal input terminal 11 of the electrical connector 1 receives an abnormal surge (lightning) signal, the high current of the surge (lightning) signal will be transmitted through the electrical connector 1 to the lightning detection circuit 2, at this time, the high current will go through the resistor 21 and then be discharged through the grounding terminal 22, and at the same time, the resistor 21 converts the high current or high voltage of the surge into a data signal and then outputs the data signal through the output terminal 23 to an external electronic device (such as host computer, surveillance system, or memory of signal processing system, CPU or IC chip capable of recording electronic signals) for storage so that the external electronic device can record the data of frequency, time or intensity of surges (lightening) occurred in the electrical connector.

For example, when the signal input terminal 11 of the electrical connector 1 receives a high current or high voltage (3 KV or 6 KV) surge, the high current is processed by the internal anti-lightning circuit (for example, resistor of impedance 40Ω) of the electrical connector 1 (for example, into 150 Amp), and then transmitted to the lightning detection circuit 2 where the resistor 21 (for example, of impedance 0.01Ω) of the lightning detection circuit 2 receives the high current and discharges it through the grounding terminal 22. At the same time, the resistor 21 converts the high current (150 Amp) into a voltage signal (about 1.5V) for output through the output terminal 23 to the connected external electronic device (host computer, surveillance system, memory of signal processing system, CPU or IC chip), enabling the external electronic device to record the frequency, time and intensity of the occurred surges (lightning). Thus, when performing a maintenance or inspection job or an updating operation, the recorded surge (lightning) related data can be fetched for maintenance reference and also for the inspection of the functioning normality of the electronic loop of the signal processing system (electronic product, computer, or electrical appliance) 12 that is electrically connected to the electrical connector 1.

As stated above, the invention provides a lightning detection circuit assembly comprising an electrical connector 1, which comprises a signal input terminal 11 and a signal processing system 12, and a lightning detection circuit 2, which comprises a resistor 21 electrically connected with one end thereof to the electrical connector 1, a grounding terminal 22 electrically connected to an opposite end of the resistor 21 and an output terminal 23 electrically connected to the end of the resistor 21 that is electrically connected to the electrical connector 1, wherein when the signal input terminal 11 of the electrical connector 1 receives a high current or high voltage of an abnormal surge (lightning), the high voltage is transmitted to the lightning detection circuit 2 and then discharged by the resistor 21 through the grounding terminal 22, and at the same time, the resistor 21 converts the surge into a data signal for output through the output terminal 23 to an external electronic device for recording, and thus the external electronic device can record the frequency, time or intensity of occurred surges (lightning) for reference in a further maintenance or inspection work, and also for the inspection of the normality of the signal processing system 12.

In conclusion, the lightning detection circuit assembly has a signal input terminal, a signal processing system and a lightning detection circuit electrically coupled to an electrical connector such that when the signal input terminal receives a high current or high voltage surge, the surge (lightning) is discharged by a resistor of the lightning detection circuit through a grounding terminal, and at the same time, the resistor converts the surge (lightning) into a data signal and provides the data signal through an output terminal to an external electronic device, enabling the external electronic device to record the frequency, time or intensity of each occurred surge (lightning) for further reference.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A lightning detection circuit assembly, comprising:
an electrical connector having a signal input terminal connected to one end thereof for receiving an external electronic signal and a signal processing system connected to an opposite end thereof for processing and transmitting electronic signals; and
a lightning detection circuit comprising a resistor electrically connected with one end thereof to said electrical connector, a grounding terminal electrically connected to an opposite end of said resistor, and an electronic device electrically coupled between said resistor and said electrical connector for receiving a current signal from said resistor.

2. The lightning detection circuit assembly as claimed in claim 1, wherein said electrical connector is a network connector, power connector or USB connector.

3. The lightning detection circuit assembly as claimed in claim 1, wherein said signal processing system of said electrical connector is a circuit board, host computer, central processing unit or IC chip of an electronic product.

4. The lightning detection circuit assembly as claimed in claim 1, wherein said electronic device is a host computer, surveillance system, memory of signal processing system, CPU or IC chip.
